(19) United States
(12) Patent Application Publication
(10) Pub. No.: US 2026/0362628 A1
(43) Pub. Date: Nov. 12, 2026

(54) CONNECTING QUANTUM PAYLOADS ACROSS MULTIPLE CRYOGENIC PLATES

(71) Applicant: International Business Machines Corporation, Armonk, NY (US)

(72) Inventors: Jason S. Orcutt, Katonah, NY (US); Theodore James Yoder, Mohegan Lake, NY (US); Andrew W. Cross, Yorktown Heights, NY (US); David Lokken-Toyli, White Plains, NY (US); Shawn Anthony Hall, Pleasantville, NY (US); Malcolm Scott Carroll, Cranbury, NJ (US)

(21) Appl. No.: 18/601,384

(22) Filed: Mar. 11, 2024

(51) Int. Cl. H05K 7/20; G06N 10/40

(52) U.S. Cl. CPC H05K 7/20; G06N 10/40

(57) ABSTRACT

Systems, devices and/or structures that facilitate coupling of quantum payloads across multiple cooling plates are provided. In an embodiment, a structure can comprise a plurality of cooling plates respectively comprising a set of qubit chips, a first type of l-coupler that couples adjacent qubit chips, and a second type of l-coupler that couples qubit chips located on different cooling plates.

### BACKGROUND

The subject disclosure relates to connecting quantum payloads across multiple cryogenic plates, and more specifically, to the use of different length couplers to connect quantum payloads across multiple cryogenic plates.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices and structures that comprise quantum payloads connected across multiple cooling plates are provided.

According to an embodiment, a structure can comprise a plurality of cooling plates respectively comprising a set of qubit chips; a first type of l-coupler that couples adjacent qubit chips; and a second type of l-coupler that couples qubit chips located on different cooling plates. An advantage of such a structure is that it enables the coupling of qubit chips from multiple different cooling plates, thereby facilitating greater scalability of quantum computers.

In some embodiments of the above-described structure, the first type of l-coupler can cause qubits on separate qubit chips to perform operations through standing-wave mode coupling and the second type of l-coupler can cause qubits on separate qubit chips to perform operations through itinerant photon-packet transmission. An advantage of such a structure is that the different modes of coupling can be utilized to account for the standing-wave (longitudinal) mode frequency spacing caused by the physical length of transmission lines between coupled qubit chips.

According to another embodiment, a structure can comprise a plurality of cooling plates respectively comprising a plurality of qubit chips, wherein each qubit chip comprises a plurality of qubits; a first type of l-coupler that couples adjacent qubit chips; and a second type of l-coupler that couples non-adjacent qubit chips located on different cooling plates, wherein each qubit chip of the plurality of qubit chips is coupled to two first type l-couplers and one second type of l-coupler. An advantage of such a structure is that it enables the coupling of qubit chips from multiple different cooling plates, thereby facilitating greater scalability of quantum computers.

In some embodiments of the above-described structure, the first type of l-coupler can cause qubits on separate qubit chips to perform operations through standing-wave mode coupling and the second type of l-coupler can cause qubits on separate qubit chips to perform operations through itinerant photon-packet transmission. An advantage of such a structure is that the different modes of coupling can be utilized to account for the standing-wave (longitudinal) mode frequency spacing caused by the physical length of transmission lines between coupled qubit chips.

According to another embodiment, a structure can comprise one or more cooling plates each comprising one or more qubit chips, wherein each qubit chip of the one or more comprises a plurality of qubits, wherein each of the one or more qubit chips comprise two connection points for a first type of l-coupler and one connection point for a second type of l-coupler. An advantage of such a structure is that it enables the coupling of qubit chips from multiple different cooling platers, thereby facilitating greater scalability of quantum computers.

In some embodiments of the above-described structure, the first type of l-coupler can cause qubits on separate qubit chips to perform operations through standing-wave mode coupling and the second type of l-coupler can cause qubits on separate qubit chips to perform operations through itinerant photon-packet transmission. An advantage of such a structure is that the different modes of coupling can be utilized to account for the standing-wave (longitudinal) mode frequency spacing caused by the physical length of transmission lines between coupled qubit chips.

### DESCRIPTION OF THE DRAWINGS

FIG. 1 illustrates a diagram of an example multi-cooling-plate quantum system in accordance with one or more embodiments described herein.

FIG. 2 illustrates a diagram of a second example multi-cooling-plate quantum system in accordance with one or more embodiments described herein.

FIG. 3 illustrates a diagram of a third example multi-cooling-plate quantum system in accordance with one or more embodiments described herein.

FIG. 4 illustrates a diagram of a fourth example of a multi-cooling-plate quantum system in accordance with one or more embodiments described herein.

FIGS. 5-8 illustrate examples of quantum processors in accordance with one or more embodiments described herein.

FIG. 9 illustrates a diagram of a fifth example of a multi-cooling-plate quantum system in accordance with one or more embodiments described herein.

FIG. 10 illustrates a diagram of a sixth example of a multi-cooling-plate quantum system in accordance with one or more embodiments described herein.

FIG. 11 illustrates a block diagram of an example, non-limiting system that can complete the execution of a quantum job in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

Quantum computing is generally the use of quantum-mechanical phenomena for the purpose of performing computing and information-processing functions. Quantum computing can be viewed in contrast to classical computing, which generally operates on binary values with transistors. That is, while classical computers can operate on bit values that are either 0 or 1, quantum computers operate on quantum bits (qubits) that comprise superpositions of both 0 and 1, can entangle multiple quantum bits, and use interference.

Quantum computers require that qubits be at low temperatures to operate, thus necessitating large cryostats to house the qubits. Traditionally all qubits and/or quantum processors (e.g., groupings of qubits) were placed within a single cooling stage or plate of the cryostat (e.g., monolithic) in order to simplify connections between qubits within the quantum computer. However, as quantum computers increase in size (e.g., the number of qubits and/or quantum processors), this creates issues for scalability, as traditional designs would require larger cooling stages than are feasible to construct and house. Furthermore, monolithic quantum computer designs can lead to increased maintenance downtime. For example, in a monolithic design, if the cryogenic systems fail, the entire quantum system has to shut down and be brought to room temperature for maintenance to occur, taking the entire system out of operation. In another example, if a qubit chip in a monolithic system fails, there may not be a way to route quantum operations around the failed chip, again taking the entire system out of operation while maintenance is performed.

Accordingly, there is a desire to move to designs comprising multiple cooling stages or plates, with quantum processors connected across the multiple cooling plates. However, the physical length of a transmission line coupling quantum processors determines the standing-wave (longitudinal) mode frequency spacing. This relationship is inverse such that a physical cable length of 1 meter corresponds to a frequency spacing of approximately 100 MHz, a 100 meter cable has a frequency spacing of approximately 1 MHz, and a 10 centimeter cable has a frequency spacing corresponding to approximately 1 GHz. As frequency spacing of the longitudinal modes has a strong impact of the performance of various gate operations, the varied frequency spacing poses a challenge to connecting non-adjacent quantum processors and processors located on different cooling plates.

In one or more embodiments, the present disclosure can be implemented in the form of systems, apparatuses, and or structures that can address the above identified issues with multi-cooling plate quantum computers. For example, as described in greater detail below, a system can comprise a plurality of cooling plates respectively comprising a set of qubit chips (alternatively referred to as quantum processors or quantum payloads), a first type of l-coupler that couples qubit chips located on the same cooling plate, and a second type of l-coupler that couples qubit chips located on different cooling plates. As used herein, an “l-coupler” can refer to any coupling pathway between two or more physically distinct quantum processors, wherein the two or more physically distinct quantum processors are not directly bump-bonded together. The first type of l-coupler can cause the coupled quantum processors to perform operations through standing-wave mode coupling, while the second type of l-coupler can cause qubits on separate quantum processors to perform operations through itinerant photon-packet transmission.

Standing-wave mode coupling enables coupling for large frequency spacing by allowing qubits to couple through a single longitudinal mode of the cable as either a bright or dark state. Accordingly, this enables qubits chips that are located adjacent to each other to couple due to the large frequency spacing between nearby qubit chips. Itinerant photon-packet transmission enables coupling for small frequency spacing. Due to the small frequency spacing, the qubits are strongly coupled to the coupling cable (e.g., with a coupling strength equal to or greater than the mode spacing) in a time-varying pulse to “pitch” and “catch” itinerant photon wave packets. Accordingly, this allows qubit chips that are located at relatively far distances, (e.g., on separate cooling plates on quantum processors that are non-adjacent) to be coupled to produce high-fidelity results. The use of the multiple types of l-couplers enables the connection of all qubit chips (alternatively referred to as payloads or quantum processors) to form a linear-chain or tree-network architecture. Additionally, it allows for connections beyond a single cooling plate, where different payload-to-payload spacing may be required. For example, as the system is spread across multiple cooling plates, if one of the cooling plates fails, only the quantum processors on that cooling plate can be taken out of operation, rather than the entire system. In another example, the linear-chain architecture allows for quantum operations to be routed around quantum processor exhibiting failures or errors, thereby preventing the failure of a single quantum processor from shutting down the entire system.

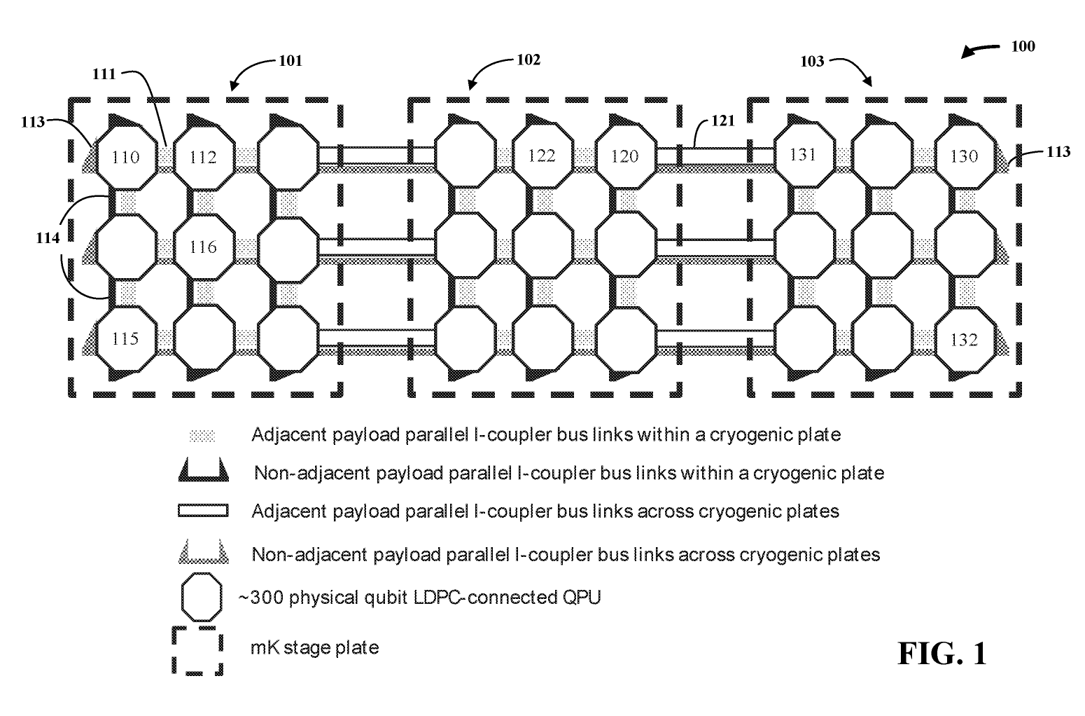

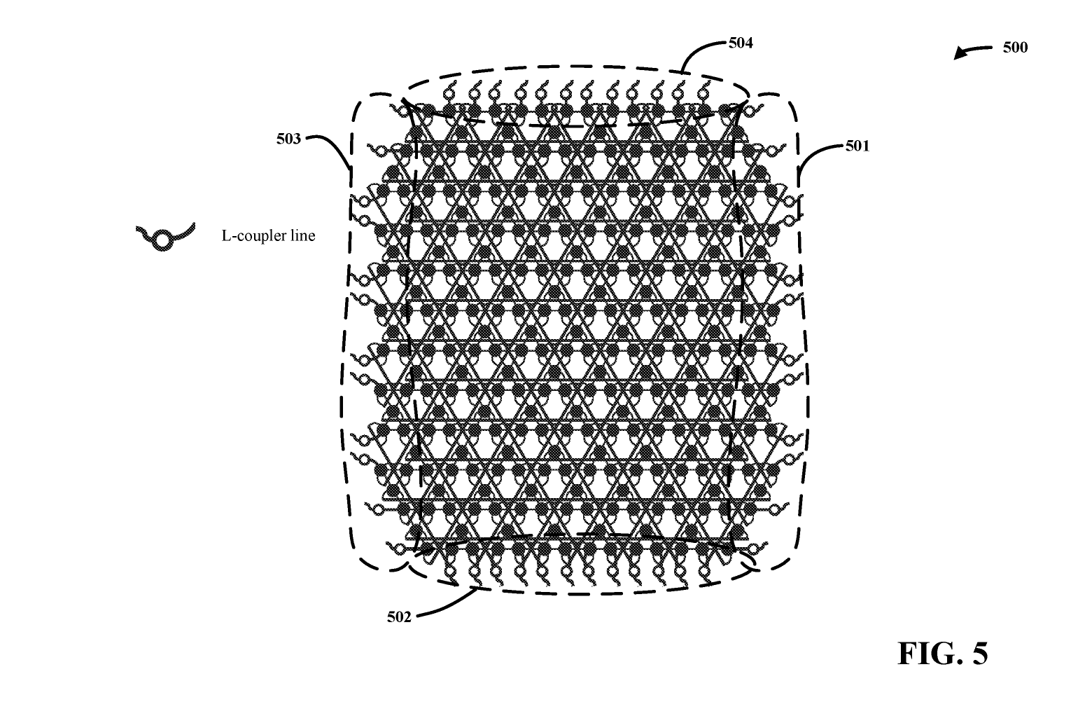

FIG. 1 illustrates a diagram of an example multi-cooling-plate quantum system 100 in accordance with one or more embodiments described herein. As shown, system 100 comprises first cooling plate 101, second cooling plate 102 and third cooling plate 103. Each of the three cooling plates as shown comprises nine quantum processors (alternatively referred to as qubit chips or quantum payloads), wherein each quantum processor comprises a plurality of qubits. System 100 also comprises four types of l-couplers for coupling the various quantum processors together. The first type of l-coupler can couple adjacent quantum processors located on the same cooling plate, the second type of l-coupler can couple non-adjacent quantum processors together across different mK-stage cooling plates, the third type of l-coupler can couple non-adjacent quantum processors on the same cooling plate and the fourth type of l-coupler can couple adjacent quantum processor located on different cooling plates. For example, quantum processor 110 is adjacent to quantum processor 112 and both quantum processors 110 and 112 are located on cooling plate 101. Accordingly, quantum processors 110 and 112 are coupled using a first type l-coupler 111. Quantum processors 110 and 130 are located on different cooling plates (cooling plates 101 and 103 respectively) and are non-adjacent. Accordingly, quantum processors 110 and 130 are coupled using a second type l-coupler 113. Quantum processors 110 and 115 are both located on cooling plate 101 but are non-adjacent. Accordingly, quantum processors 110 and 115 are coupled using third type l-coupler 114. Quantum processors 120 and 131 are adjacent but located on different cooling plates (cooling plates 102 and 103 respectively). Accordingly, quantum processors 120 and 131 are coupled using fourth type l-coupler 121. It should be appreciated that in some embodiments, the l-couplers as described herein can comprise a plurality of individual l-coupler lines. For example, as described below in more detail in relation to FIG. 5, given a quantum processor with a connection edge or connection point for twelve individual coupler lines, the l-coupler can comprise a bundle of twelve individual coupler lines. In an embodiment, due to the short physical length, the first type l-couplers can facilitate coupling through standing-wave mode coupling, while the second, third and fourth type l-couplers can facilitate coupling through itinerant photon-packet transmission due to the longer physical distances.

As shown in FIG. 1, the nine-processor layout of each cooling plate allows for standardization of the various types of couplers, allowing for easier production. Further, the design as shown allows for a constant degree of connectivity and vertex transitiveness between all qubits within the system due to the interconnected design. For example, quantum processor 112 can connect with quantum processor 130 (through quantum processor 110) despite not being directly coupled. Furthermore, there are multiple pathways from any one quantum processor to any other, enabling a high degree of redundancy in the event of failure of one or more quantum processors. This also allows for greater flexibility in operations and greater tolerance to failure of a quantum processor or all the quantum processors on a cooling plate. For example, if quantum processor 120 were to fail or break, quantum processor 122 can still connect to quantum processor 131 through one of several alternative connective pathways.

If all the quantum processors on cooling plate 102 were to fail, quantum processors on cooling plate 101 can still connect to those on cooling plate 103 via the second type l-couplers. This adds redundancy to the system that allows for continued execution of quantum operations, even in the event that multiple quantum processors or an entire cooling plate were to fail or experienced operating errors. The design of system 100 allows for better control of heat balancing within the system. For example, if the temperature within one of the cooling plates were to rise due to the workload of the quantum processors, or a partial failure of the cryogenics of the cooling plate, some of the workload of the processors of the cooling plate can be routed to quantum processors on the other cooling plates to balance the heat load. This can enable quantum processors on a cooling plate experiencing a partial cryogenic failure to continue operations.

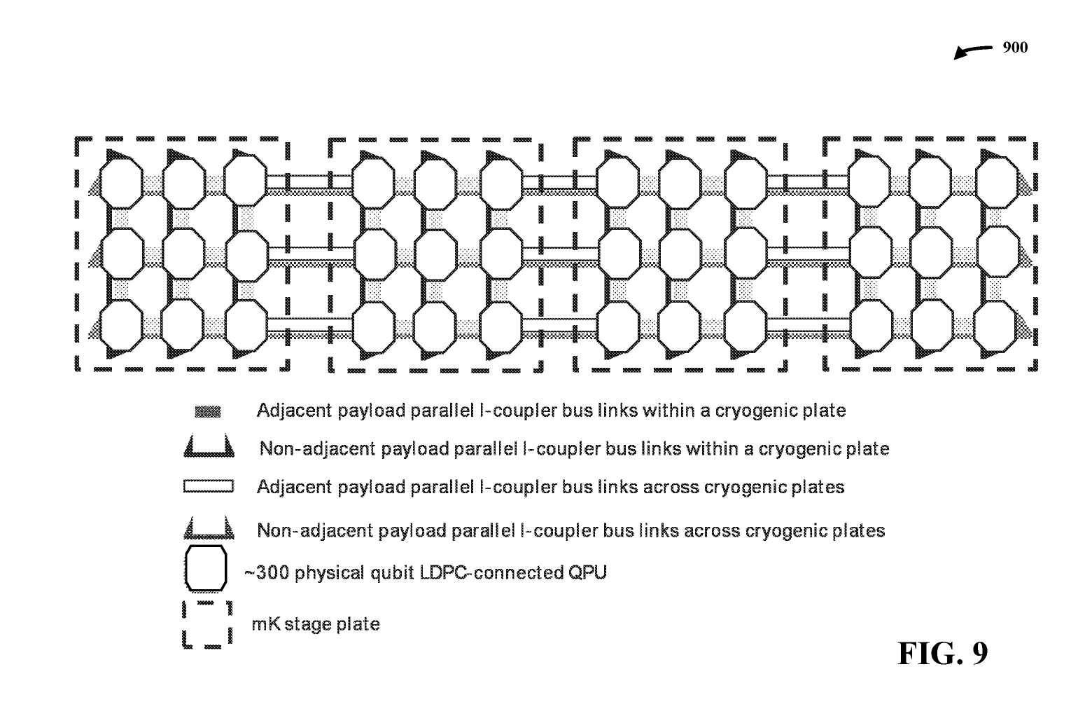

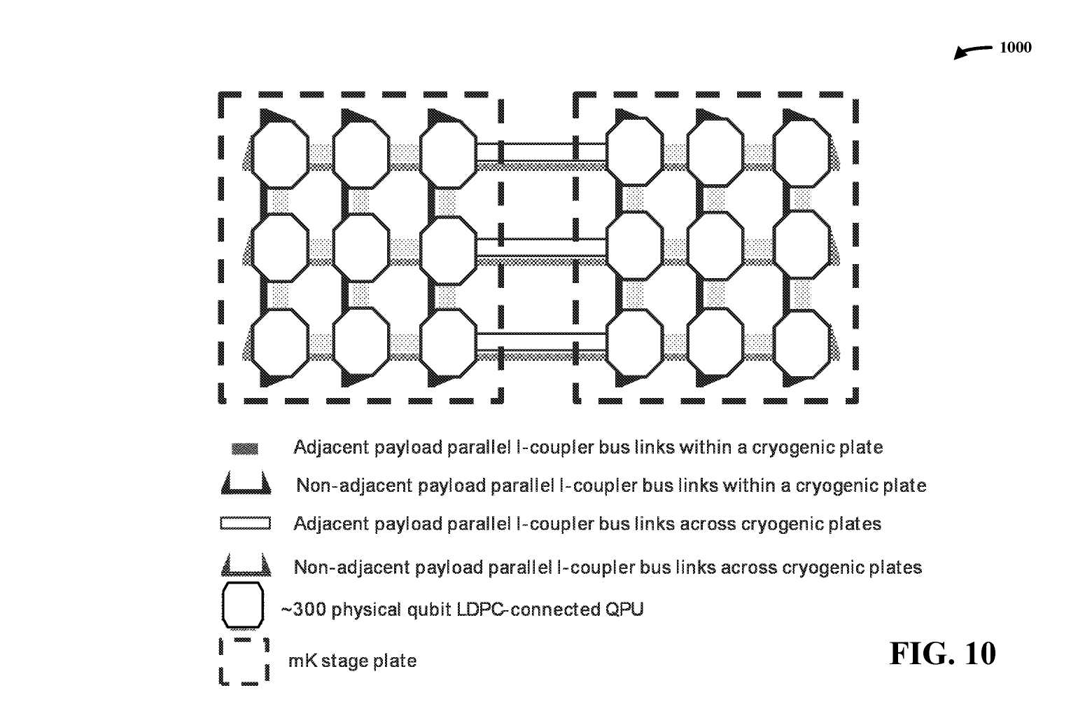

Quantum system 100 as shown can comprise multiple forms of quantum processors to accommodate the specified types of l-couplers. For example, quantum processor 110 can comprise two connection points or edges for first type l-couplers, one connection point for a second type l-coupler and one connection point for a third type l-coupler. Quantum processor 112 can comprise three connection points for first type l-couplers and one connection point for a third type l-coupler. Quantum processor 116 can comprise four connection points for first type l-couplers. Quantum processor 120 can comprise two connection points for first type l-couplers, one connection point for a third type l-coupler and one connection point for a fourth type l-coupler. It should be appreciated that although system 100 is shown with three cooling plates, in one or more embodiments, use of more cooling plates is envisioned. For example, one or more additional interior cooling plates (e.g., cooling plates with a quantum processor layout like that of cooling plate 102) can be inserted between cooling plates 102 and 101 or between cooling plates 102 and 103 as shown in system 900 of FIG. 9. Further in one or more embodiments, the interior cooling plates can be omitted, and exterior cooling plates (such as cooling plates 101 and 103) can be directly coupled as shown in system 1000 of FIG. 10.

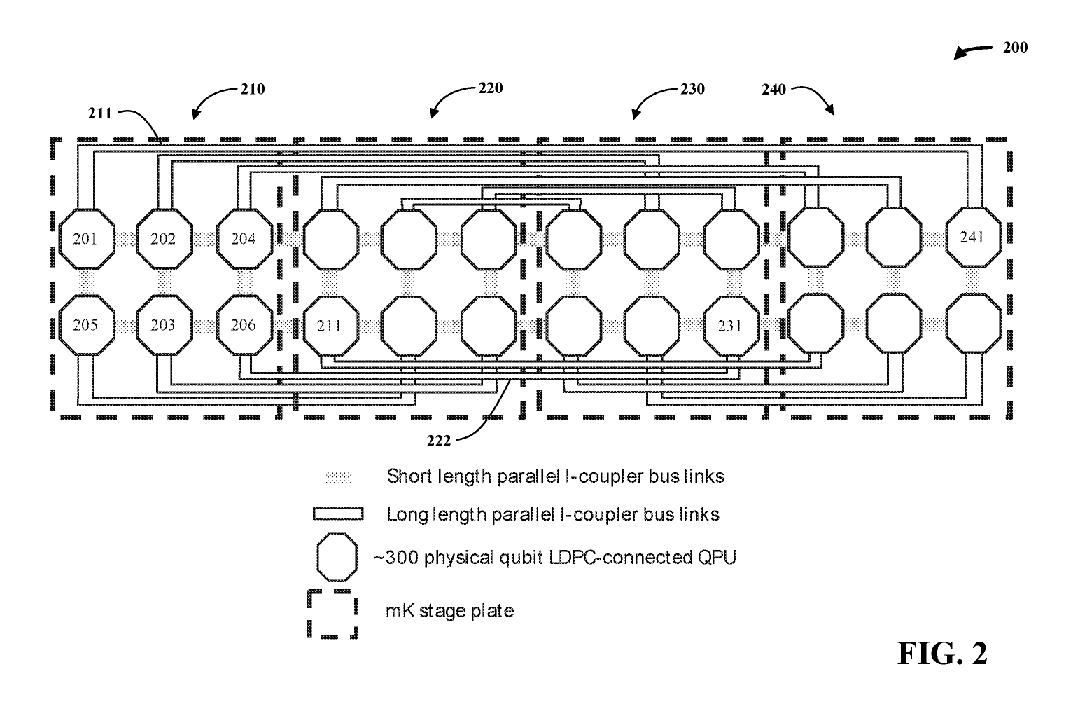

FIG. 2 illustrates a diagram of a second example multi-cooling-plate quantum system 200 in accordance with one or more embodiments described herein. As shown, quantum system 200 comprises four mK-stage cooling plates (cooling plates 210, 220, 230 and 240), wherein each cooling plate comprises six quantum processors. System 200 further comprises a first type of l-coupler that couples adjacent quantum processors and a second type of l-coupler that couples non-adjacent quantum processors across different cooling plates. For example, quantum processor 201 is coupled to quantum processors 202 and 205 via first type l-couplers and to quantum processor 241 via a second type l-coupler 211. Similarly, quantum processor 206 is coupled to adjacent quantum processors on the same cooling plate (quantum processors 204 and 203) via first type l-couplers, to an adjacent quantum processor on a separate cooling plate (quantum processor 221) and a non-adjacent quantum processor on a separate cooling plate (quantum processor 231). In an embodiment, due to the short distances between adjacent quantum processors, the first type l-couplers can operate through standing-wave mode coupling and the second type l-couplers can operate through itinerant photon-packet transmission, due to the relatively long distances between non-adjacent quantum processors.

The use of the second type l-couplers can lead to overall improved fidelity of the system. For example, while information can be passed from quantum processor 201 to quantum processor 241 through the ten intermediary quantum processors between them, this would take time and introduce noise into the information, thereby decreasing fidelity of the results. Furthermore, this would clutter the system by introducing additional operations for the intermediary processors to handle. In contrast, the second type l-coupler increases fidelity of operations between quantum processor 201 and 241 and decreases the number of operations that the intermediary processors would otherwise handle, thereby both improving speed and fidelity of the quantum operations. As shown, the quantum processors in system 200 can comprise two groups, processors such as 202 are coupled to three first type l-couplers and one second type l-coupler, and processors such as 201 are coupled to two first type l-couplers and one second type l-coupler.

It should be appreciated that interconnectivity of the quantum processors of system 200 forms multiple loops that provides a constant degree of connectivity and vertex transitiveness between the various quantum processor and redundancy in the event of hardware failure. For example, in the event one or more quantum processors were to fail, the plethora of alternative coupling pathways allows for operations to continue by routing the quantum information and operations around the broken quantum processor. In a further example, in the event an entire cooling plate or all the quantum processors on the cooling plate where to fail, then operations can be routed around the failed cooling plate using one or more of the second type l-couplers. By enabling routing around failed quantum processors, maintenance requirements can be decreased as operations can still be performed, even with the failure of multiple quantum processors. The design of system 200 allows for better control of heat balancing within the system. For example, if the temperature within one of the cooling plates were to rise due to the workload of the quantum processors, or a partial failure of the cryogenics of the cooling plate, some of the workload of the processors of the cooling plate can be routed to quantum processors on the other cooling plates to balance the heat load. This can enable quantum processors on a cooling plate experiencing a partial cryogenic failure to continue operations.

In some embodiments, system 200 can comprise multiple types of quantum processors to account for the different types and number of coupler connections utilized. For example, some quantum processors, such as quantum processor 202, can comprise connections for three first type l-couplers and one second type l-coupler, and other quantum processors, such as quantum processor 201, can comprise connections for two first type l-couplers and one second type l-coupler. By using different types of quantum processors, production costs or production time may be decreased as quantum processors with fewer connection points may be faster and/or cheaper to produce. In an alternative embodiment, all of the quantum processors of system 200 can comprise the same processor type, with some connection points left un-attached. For example, quantum processor 201 can comprise three connection points for first type l-couplers and one connection point for a second type l-coupler, with one of the connection points for a first type l-coupler unused. By standardizing to a single form of quantum processor, production lines can be simplified, which may lead to decreased production costs and time.

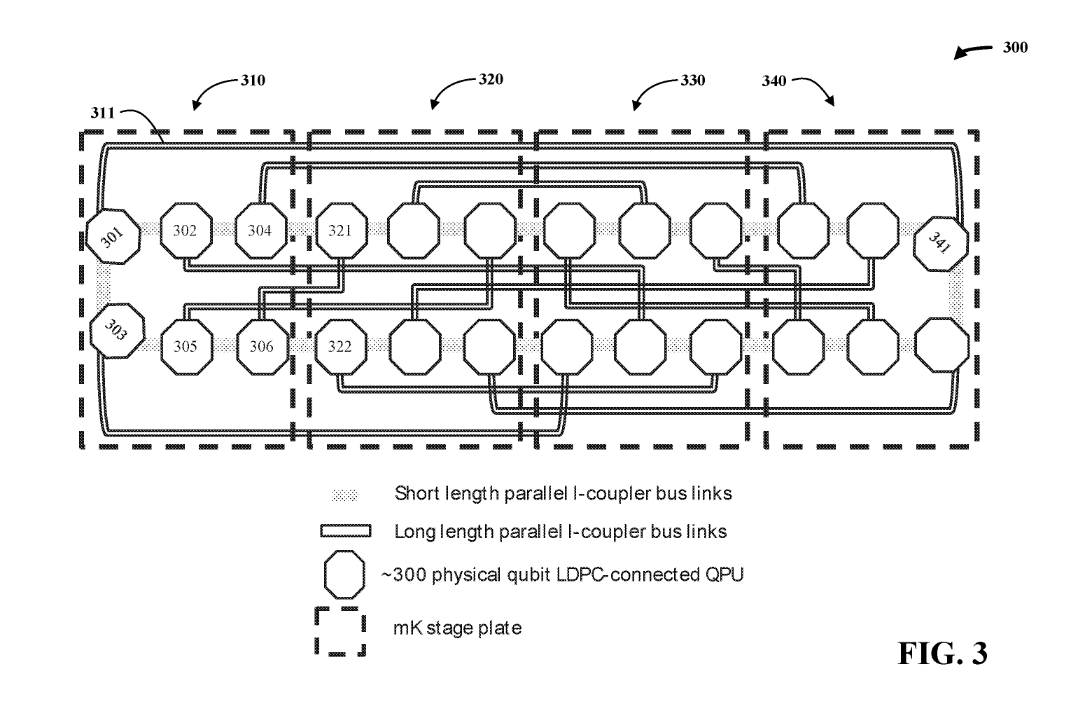

FIG. 3 illustrates a diagram of a third example multi-cooling-plate quantum system 300 in accordance with one or more embodiments described herein. As shown, quantum system 300 comprises four mK-stage cooling plates (cooling plates 310, 320, 330 and 340), wherein each cooling plate comprises six quantum processors. System 300 further comprises a first type of l-coupler that couples adjacent quantum processors and a second type of l-coupler that couples non-adjacent quantum processors across different cooling plates. For example, quantum processor 301 is coupled to quantum processors 302 and 303 via first type l-couplers and to quantum processor 341 via a second type l-coupler 311. Similarly, quantum processor 306 is coupled to an adjacent quantum processor on the same cooling plate (quantum processor 305) via a first type l-coupler, to an adjacent quantum processor on a separate cooling plate (quantum processor 322) and a non-adjacent quantum processor on a separate cooling plate (quantum processor 321). In an embodiment, due to the short distances between adjacent quantum processors, the first type l-couplers can operate through standing-wave mode coupling and the second type l-couplers can operate through itinerant photon-packet transmission, due to the relatively long distances between non-adjacent quantum processors.

The use of the second type l-couplers can lead to overall improved fidelity of the system. For example, while information can be passed from quantum processor 301 to quantum processor 341 through the ten intermediary quantum processors between them, this would take time and introduce noise into the information, thereby decreasing fidelity of the results. Furthermore, this would clutter the system by introducing additional operations for the intermediary processors to handle. In contrast, the second type l-coupler increases fidelity of operations between quantum processor 301 and 341 and decreases the number of operations that the intermediary processors would otherwise handle, thereby both improving speed and fidelity of the quantum operations.

It should be appreciated that interconnectivity of the quantum processors of system 300 forms multiple loops that provide redundancy in the event of hardware failure. For example, in the event one or more quantum processors were to fail, the plethora of alternative coupling pathways allows for operations to continue by routing the quantum information and operations around the broken quantum processor. In a further example, in the event an entire cooling plate or all the quantum processors on the cooling plate where to fail, then operations can be routed around the failed cooling plate using one or more of the second type l-couplers. By enabling routing around failed quantum processors, maintenance requirements can be decreased as operations can still be performed, even with the failure of multiple quantum processors. The design of system 300 allows for better control of heat balancing within the system. For example, if the temperature within one of the cooling plates were to rise due to the workload of the quantum processors, or a partial failure of the cryogenics of the cooling plate, some of the workload of the processors of the cooling plate can be routed to quantum processors on the other cooling plates to balance the heat load. This can enable quantum processors on a cooling plate experiencing a partial cryogenic failure to continue operations.

In one or more embodiments, all quantum processors of system 300 can comprise the same processor type, with two connections for first type l-couplers and one connection for second type l-couplers. The use of a single type of quantum processor can decrease production costs, time and maintenance wait times due to standardization. In one or more embodiments, one or more quantum processors of system 300 can comprise one or more un-used connection points. For example, one or more quantum processors of system 300 can comprise a fourth un-used connection point. This can enable the connection of additional quantum processors in the future or enable use of quantum processor types originally designed for use in other system layouts.

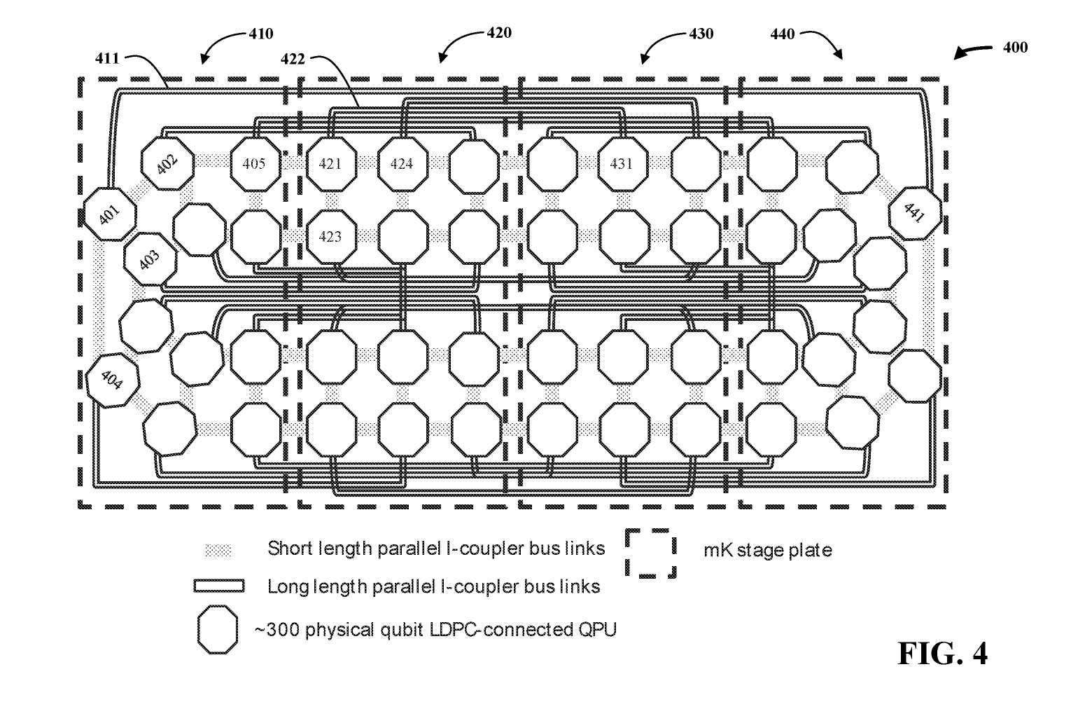

FIG. 4 illustrates a diagram of a fourth example of a multi-cooling-plate quantum system 400 in accordance with one or more embodiments described herein. As shown, quantum system 400 comprises four mK-stage cooling plates (cooling plates 410, 420, 430 and 440), wherein each cooling plate comprises twelve quantum processors. System 400 further comprises a first type of l-coupler that couples adjacent quantum processors and a second type of l-coupler 0that couples non-adjacent quantum processors across different cooling plates. For example, quantum processor 401 is coupled to quantum processors 402, 403 and 404 via first type l-couplers and to quantum processor 441 via a second type l-coupler 411. Similarly, quantum processor 421 is coupled to adjacent quantum processors on the same cooling plate (quantum processors 423 and 424) via first type l-couplers, to an adjacent quantum processor on a separate cooling plate (quantum processor 405) and a non-adjacent quantum processor on a separate cooling plate (quantum processor 431). In an embodiment, due to the short distances between adjacent quantum processors, the first type l-couplers can operate through standing-wave mode coupling and the second type l-couplers can operate through itinerant photon-packet transmission, due to the relatively long distances between non-adjacent quantum processors.

The use of the second type l-couplers can lead to overall improved fidelity of the system. For example, while information can be passed from quantum processor 401 to quantum processor 441 through the ten intermediary quantum processors between them, this would take time and introduce noise into the information, thereby decreasing fidelity of the results. Furthermore, this would clutter the system by introducing additional operations for the intermediary processors to handle. In contrast, the second type l-coupler increases fidelity of operations between quantum processor 401 and 441 and decreases the number of operations that the intermediary processors would otherwise handle, thereby both improving speed and fidelity of the quantum operations.

It should be appreciated that interconnectivity of the quantum processors of system 400 forms multiple loops that provide redundancy in the event of hardware failure. For example, in the event one or more quantum processors were to fail, the plethora of alternative coupling pathways allows for operations to continue by routing the quantum information and operations around the broken quantum processor. In a further example, in the event an entire cooling plate or all the quantum processors on the cooling plate where to fail, then operations can be routed around the failed cooling plate using one or more of the second type l-couplers. By enabling routing around failed quantum processors, maintenance requirements can be decreased as operations can still be performed, even with the failure of multiple quantum processors. The design of system 400 allows for better control of heat balancing within the system. For example, if the temperature within one of the cooling plates were to rise due to the workload of the quantum processors, or a partial failure of the cryogenics of the cooling plate, some of the workload of the processors of the cooling plate can be routed to quantum processors on the other cooling plates to balance the heat load. This can enable quantum processors on a cooling plate experiencing a partial cryogenic failure to continue operations.

In one or more embodiments, all quantum processors of system 400 can comprise the same processor type, with three connections for first type l-couplers and one connection for second type l-couplers. The use of a single type of quantum processor can decrease production costs, time and maintenance wait times due to standardization.

FIG. 5 illustrates a non-limiting example of a quantum processor 500 in accordance with one or more embodiments described herein. In an embodiment, quantum processor 500 can comprise approximately 300 qubits, degree-6 connectivity, with each qubit being coupled to four local gates and two long-distance gates on quantum processor 500. In one or more embodiments, quantum processor 500 can implement a low-density parity check (LDPC) code block. As shown, quantum processor 500 comprises four connection edges, edge 501, edge 502, edge 503 and edge 504. Each connection edge can comprise twelve endpoints, allowing for coupling to an l-coupler comprising twelve individual coupling lines. In one or more embodiments, the edges can be optimized for or connected to various different types of l-couplers as described herein. For example, quantum processor 500 can be utilized in the position of quantum processor 110 of FIG. 1. Accordingly, connection edges 501 and 502 can be coupled to first type l-couplers of FIG. 1, such as first type l-coupler 111, connection edge 503 can be coupled to a second type of l-coupler of FIG. 1, and connection edge 504 can be coupled to a third type of l-coupler of FIG. 1.

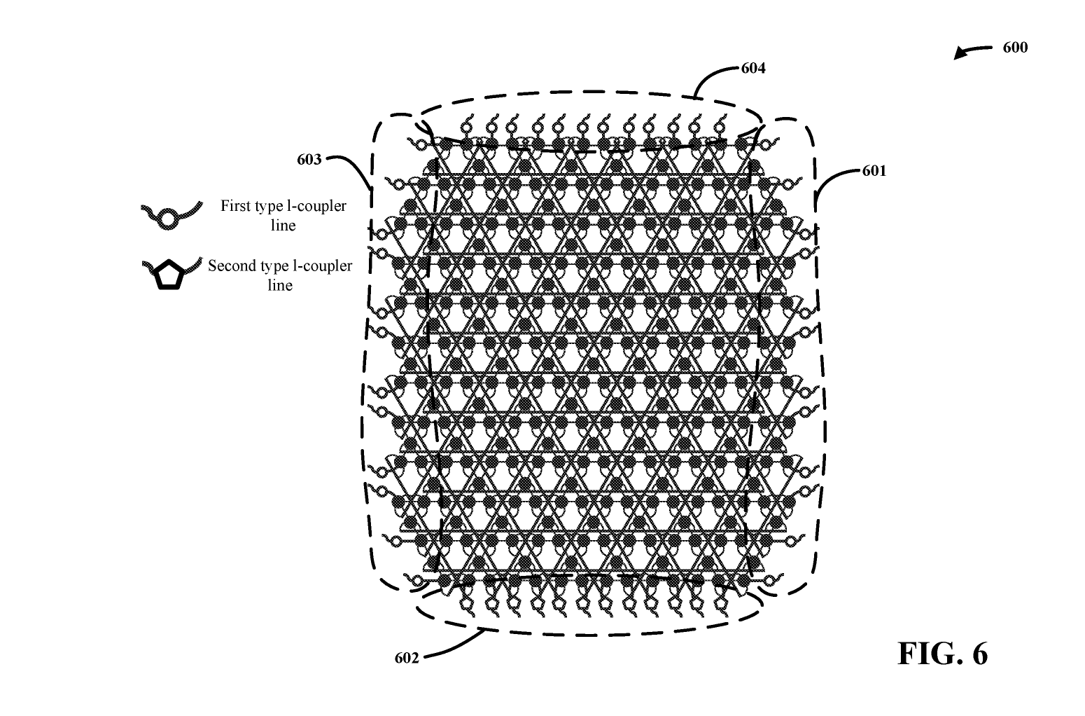

FIG. 6 illustrates a non-limiting example of a quantum processor 600 in accordance with one or more embodiments described herein. In an embodiment, quantum processor 600 can comprise approximately 300 qubits, degree-6 connectivity, with each qubit being coupled to four local gates and two long-distance gates on quantum processor 600. In one or more embodiments, quantum processor 600 can implement a low-density parity check (LDPC) code block. As shown, quantum processor 600 comprises four connection edges, edge 601, edge 602, edge 03 and edge 604. Each connection edge can comprise twelve endpoints, allowing for coupling to an l-coupler comprising twelve individual coupling lines. In one or more embodiments, the edges can be optimized for or connected to various different types of l-couplers as described herein. As shown, quantum processor 600 is coupled to first type l-couplers at edges 601, 603 and 604 and to a second type l-coupler at connection edge 602. For example, as shown, quantum processor 600 can be utilized in the position of quantum processor 202 of FIG. 2, wherein edge 601 couples to quantum processor 201, edge 602 couples to quantum processor 241, edge 603 couples to quantum processor 204 and edge 604 couples to quantum processor 203. In another example, quantum processor 600 can be utilized in the position of quantum processor 401 of FIG. 4, wherein edge 601 couples to quantum processor 404, edge 602 couples to quantum processor 441, edge 603 couples to quantum processor 402 and edge 604 couples to quantum processor 203.

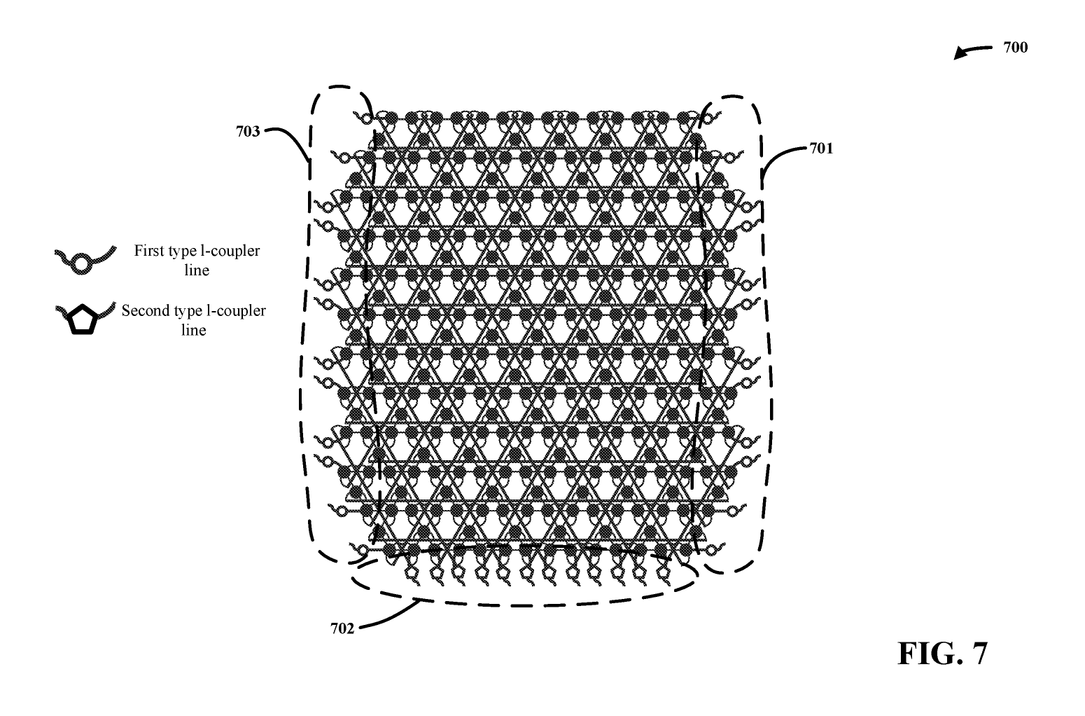

FIG. 7 illustrates a non-limiting example of a quantum processor 700 in accordance with one or more embodiments described herein. In an embodiment, quantum processor 700 can comprise approximately 300 qubits, degree-6 connectivity, with each qubit being coupled to four local gates and two long-distance gates on quantum processor 700. In one or more embodiments, quantum processor 700 can implement a low-density parity check (LDPC) code block. As shown, quantum processor 700 comprises three connection edges, edge 701, edge 702 and edge 703. Each connection edge can comprise twelve endpoints, allowing for coupling to an l-coupler comprising twelve individual coupling lines. In one or more embodiments, the edges can be optimized for or connected to various different types of l-couplers as described herein. As shown, quantum processor 700 is coupled to first type l-couplers at edges 701 and 703 and to a second type l-coupler at connection edge 702. For example, as shown, quantum processor 700 can be utilized in the position of quantum processor 301 of FIG. 3, wherein edge 701 couples to quantum processor 303, edge 702 couples to quantum processor 341, and edge 703 couples to quantum processor 302.

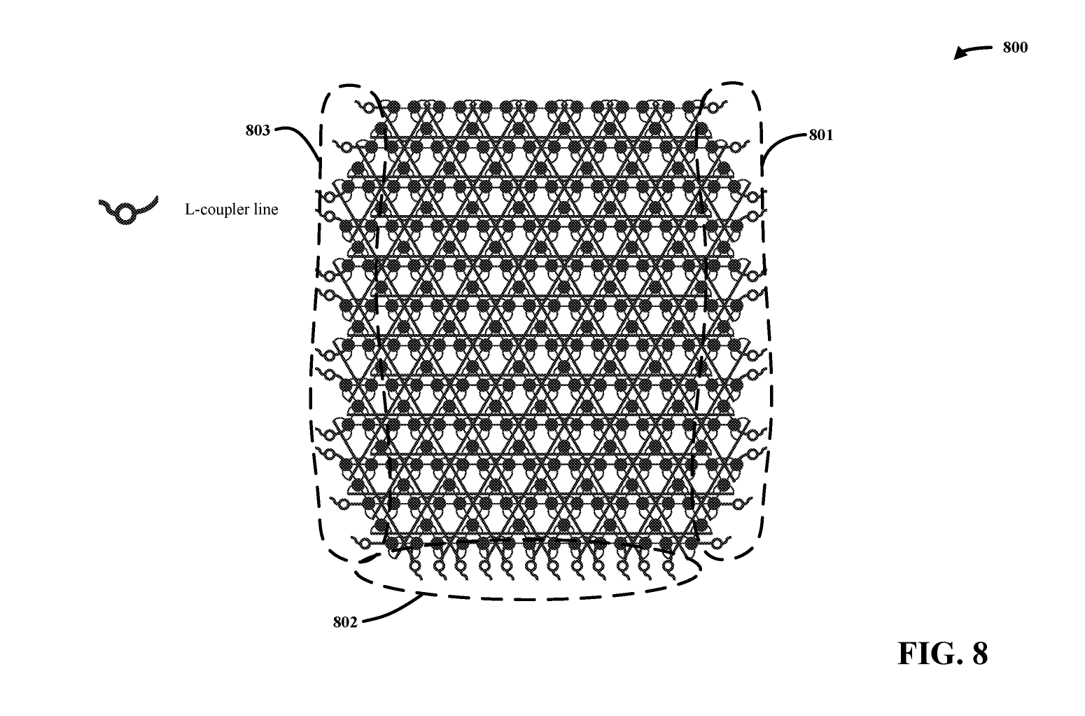

FIG. 8 illustrates a non-limiting example of a quantum processor 800 in accordance with one or more embodiments described herein. In an embodiment, quantum processor 800 can comprise approximately 300 qubits, degree-6 connectivity, with each qubit being coupled to four local gates and two long distance gates on quantum processor 800. In one or more embodiments, quantum processor 800 can implement a low-density parity check (LDPC) code block. As shown, quantum processor 800 comprises three connection edges, edge 801, edge 802 and edge 803. Each connection edge can comprise twelve endpoints, allowing for coupling to an l-coupler comprising twelve individual coupling lines. In one or more embodiments, the edges can be optimized for or connected to various different types of l-couplers as described herein. As shown, quantum processor 800 is coupled to first type l-couplers at edges 801, 802 and 803.

A practical application of the quantum system designs described herein is that they enable greater scalability and redundancy in comparison to monolithic quantum systems. For example, by using different forms of coupling based on the physical length of the coupling cables, high fidelity coupling between distinct quantum processors can be achieved over greater distances. This enables an increased number of quantum processors in quantum systems and allows for the quantum processors to be spread among multiple cooling plates. This eases production due to size constraints of cooling plates and adds redundancy and resistance to cryogenic or quantum processor failures. For example, if the cryogenics of a cooling plate were to fail, then quantum operations can be routed to quantum processors located on other cooling plates. In another example, if the cryogenics of a cooling plate were to partially fail, then some of the quantum operations can be routed to quantum processors on other cooling plates to decrease the heat load on the partially failed cooling plate. The constant connectivity and vertex transitiveness of the designs also adds redundancy in the event of failure of one or more of the quantum processors. For example, if one or more individual quantum processors were to fail, then quantum operations can be routed around the failed processors, allowing the system to continue operations.

It is to be appreciated that the quantum systems described herein can utilize various combination of electrical components, mechanical components, and circuity that cannot be replicated in the mind of a human or performed by a human as the various operations that can be executed by the quantum systems and/or components thereof as described herein are operations that are greater than the capability of a human mind. For instance, the amount of data processed, the speed of processing such data, or the types of data processed by system over a certain period of time can be greater, faster, or different than the amount, speed, or data type that can be processed by a human mind over the same period of time. According to several embodiments, the system can also be fully operational towards performing one or more other functions (e.g., fully powered on, fully executed, and/or another function) while also performing the various operations described herein. It should be appreciated that such simultaneous multi-operational execution is beyond the capability of a human mind. It should be appreciated that the systems can include information that is impossible to obtain manually by an entity, such as a human user. For example, the type, amount, and/or variety of information included in the quantum systems can be more complex than information obtained manually by an entity, such as a human user.

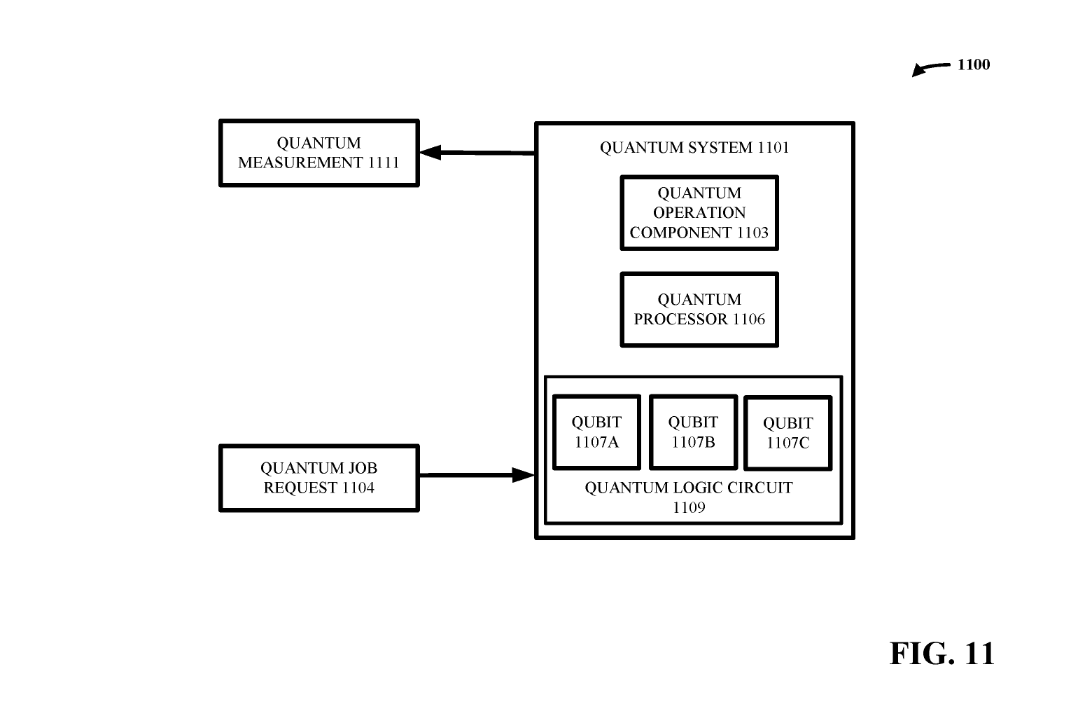

Turning generally to FIG. 11, one or more embodiments described herein (e.g., systems 100-400, and 900-1000) can include one or more devices, systems and/or apparatuses that can facilitate executing one or more quantum operations to facilitate output of one or more quantum results. For example, FIG. 11 illustrates a block diagram of an example, non-limiting system 1100 that can complete the execution of a quantum job.

The quantum system 1101 (e.g., quantum computer system, superconducting quantum computer system and/or the like) can employ quantum algorithms and/or quantum circuitry, including computing components and/or devices, to perform quantum operations and/or functions on input data to produce results that can be output to an entity. The quantum circuitry can comprise quantum bits (qubits), physical circuit level components, high level components and/or functions. The quantum circuity can comprise physical pulses that can be structured (e.g., arranged and/or designed) to perform desired quantum functions and/or computations on data (e.g., input data and/or intermediate data derived from input data) to produce one or more quantum results as an output. The quantum results, e.g., quantum measurement 1111, can be responsive to the quantum job request 1104 and associated input data and can be based at least in part on the input data, quantum functions and/or quantum computations.

In one or more embodiments, the quantum system 1101 can comprise one or more quantum components, such as a quantum operation component 1103, a quantum processor 1106 and a quantum logic circuit 11011 comprising one or more qubits (e.g., qubits 1107A, 1107B and/or 1107C), also referred to herein as qubit devices 1107A, 1107B and 1107C. The quantum processor 1106 can be any suitable processor, capable of controlling qubit coherence and the like. The quantum processor 1106 can generate one or more instructions for controlling the one or more processes of the quantum operation component 1103.

The quantum operation component 1103 that can obtain (e.g., download, receive, search for and/or the like) a quantum job request 1104 requesting execution of one or more quantum programs. The quantum operation component 1103 can determine one or more quantum logic circuits, such as the quantum logic circuit 11011, for executing the quantum program. The request 1104 can be provided in any suitable format, such as a text format, binary format and/or another suitable format. In one or more embodiments, the request 1104 can be received by a component other than a component of the quantum system 1101, such as a by a component of a classical system coupled to and/or in communication with the quantum system 1101.

The quantum operation component 1103 can perform one or more quantum processes, calculations and/or measurements for operating one or more quantum circuits on the one or more qubits 1107A, 1107B and/or 1107C. For example, the quantum operation component 1103 can operate one or more qubit effectors, such as qubit oscillators, harmonic oscillators, pulse generators and/or the like to cause one or more pulses to stimulate and/or manipulate the state(s) of the one or more qubits 1107A, 1107B and/or 1107C comprised by the quantum system 1101. That is, the quantum operation component 1103, such as in combination with the quantum processor 1106, can execute operation of a quantum logic circuit on one or more qubits of the circuit (e.g., qubit 1107A, 1107B and/or 1107C). The quantum operation component 1103 can output one or more quantum job results, such as one or more quantum measurements 111111, in response to the quantum job request 1104.

It will be appreciated that the following description(s) refer(s) to the operation of a single quantum program from a single quantum job request. However, it also will be appreciated that one or more of the processes described herein can be scalable, such as execution of one or more quantum programs and/or quantum job requests in parallel with one another.

In one or more embodiments, the non-limiting system 1100 can be a hybrid system and thus can include both one or more classical systems, such as a quantum program implementation system, and one or more quantum systems, such as the quantum system 1101. In one or more other embodiments, the quantum system 1101 can be separate from, but function in combination with, a classical system.

In such case, one or more communications between one or more components of the non-limiting quantum system 1100 and a classical system can be facilitated by wired and/or wireless means including, but not limited to, employing a cellular network, a wide area network (WAN) (e.g., the Internet), and/or a local area network (LAN). Suitable wired or wireless technologies for facilitating the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an ANT, an ultra-wideband (UWB) standard protocol and/or other proprietary and/or non-proprietary communication protocols.

What is claimed is:

1. A structure comprising:
a plurality of cooling plates respectively comprising a set of qubit chips;
a first type of l-coupler that couples adjacent qubit chips; and
a second type of l-coupler that couples qubit chips located on different cooling plates.

2. The structure of claim 1, wherein the first type of l-coupler causes qubits on separate qubit chips to perform operations through standing-wave mode coupling.

3. The structure of claim 1, wherein the second type of l-coupler causes qubits on separate qubit chips to perform operations through itinerant photon-packet transmission.

4. The structure of claim 1, wherein each qubit chip has a constant degree of connectivity with other qubit chips of the structure.

5. The structure of claim 1, wherein the first type of l-couplers couple adjacent qubit chips located on the same cooling plate and wherein the second type of l-coupler couples qubit chips located on different, non-adjacent cooling plates.

6. The structure of claim 5, further comprising:
a third type of l-coupler that couples non-adjacent qubit chips located on the same cooling plate; and
a fourth type or l-coupler that couples adjacent qubit chips located on different, adjacent cooling plates.

7. The structure of claim 1, wherein each qubit chip of the set of qubit chips is coupled to two first type l-couplers and one second type of l-coupler.

8. The structure of claim 1, wherein each qubit chip of the set of qubit chips is coupled to three first type l-couplers and one second type of l-coupler.

9. The structure of claim 1, wherein each qubit chip in a first group of qubit chips of the plurality of qubit chips is coupled to two first type l-couplers and one second type of l-coupler and wherein each qubit chip in a second group of qubit chips of the plurality of qubit chips is coupled to three first type l-couplers and one second type of l-coupler.

10. A structure comprising:
a plurality of cooling plates respectively comprising a plurality of qubit chips, wherein each qubit chip comprises a plurality of qubits;
a first type of l-coupler that couples adjacent qubit chips; and
a second type of l-coupler that couples non-adjacent qubit chips located on different cooling plates, wherein each qubit chip of the plurality of qubit chips is coupled to two first type l-couplers and one second type of l-coupler.

11. The structure of claim 10, wherein the first type of l-coupler causes qubits on separate qubit chips to perform operations through standing-wave mode coupling.

12. The structure of claim 10, wherein the second type of l-coupler causes qubits on separate qubit chips to perform operations through itinerant photon-packet transmission.

13. The structure of claim 10, wherein each qubit chip has a constant degree of connectivity with other qubit chips of the structure.

14. The structure of claim 10, wherein each qubit chip has vertex transitiveness.

15. A structure comprising:
one or more cooling plates each comprising one or more qubit chips, wherein each qubit chip of the one or more comprises a plurality of qubits, wherein each of the one or more qubit chips comprise two connection points for a first type of l-coupler and one connection point for a second type of l-coupler.

16. The structure of claim 15, wherein the first type of l-coupler couples devices located on a shared cooling plate.

17. The structure of claim 15, wherein the second type of l-coupler couples devices located on separate cooling plates.

18. The structure of claim 15, wherein each qubit chip of the one or more qubit chips comprises three connection points for the first type of l-coupler.

19. The structure of claim 15, wherein the first type of l-coupler enables standing-wave mode coupling.

20. The structure of claim 15, wherein the second type of l-couple enables itinerant photon-packet transmission coupling.
